(19) United States
(12) Patent Application Publication
(10) Pub. No.: US 2023/0335451 A1
(43) Pub. Date: Oct. 19, 2023

(54) ELECTRONIC COMPONENT PACKAGE

(71) Applicant: Murata Manufacturing Co., Ltd., Kyoto-fu (JP)

(72) Inventors: Takamitsu NAKAMURA, Nagaokakyo-shi (JP); Hideo NAKAGOSHI, Nagaokakyo-shi (JP); Kensuke OTAKE, Nagaokakyo-shi (JP); Hiroki YOSHIMORI, Nagaokakyo-shi (JP)

(21) Appl. No.: 18/333,036

(22) Filed: Jun. 12, 2023

Related U.S. Application Data
(63) Continuation of application No. PCT/JP2021/044894, filed on Dec. 7, 2021.

(30) Foreign Application Priority Data
Dec. 14, 2020 (JP) 2020-206939

(51) Int. Cl. H01L 23/552; H01L 23/31; H01L 21/56; H01L 23/495; H01L 25/16

(52) U.S. Cl. CPC H01L 23/3107; H01L 21/568; H01L 23/495; H01L 23/552; H01L 25/16

(57) ABSTRACT

An electronic component package includes: a resin portion having a first surface; one or more electronic components each having a plurality of external electrodes; and a plurality of extraction electrodes electrically connected to the plurality of external electrodes. Only each of the plurality of extraction electrodes is exposed from the resin portion on the first surface. The plurality of external electrodes are covered with the resin portion.

### CROSS REFERENCE TO RELATED APPLICATION

This is a continuation of International Application No. PCT/JP2021/044894 filed on Dec. 7, 2021 which claims priority from Japanese Patent Application No. 2020-206939 filed on Dec. 14, 2020. The contents of these applications are incorporated herein by reference in their entireties.

### BACKGROUND OF THE DISCLOSURE

### Field of the Disclosure

The present disclosure relates to an electronic component package.

### Description of the Related Art

An exemplary electronic component package is described in WO 2019/139072A1 (PTL 1). In the electronic component package described in PTL 1, an electronic component is disposed to be covered with a resin layer, and an external electrode of the electronic component is exposed to outside from the resin layer. When the electronic component includes a solder bump as the external electrode, a portion of the solder bump is exposed from the resin layer.

PTL 1: WO 2019/139072A1

### BRIEF SUMMARY OF THE DISCLOSURE

As described in PTL 1, in the case where the external electrode of the electronic component disposed inside the resin layer is directly exposed to the outside of the resin layer, there is a possibility that when mounting the electronic component package, a constricted shape is formed in the external electrode to break the bump, thus resulting in a problem of reliability.

Thus, a possible benefit of the present disclosure is to provide an electronic component package to increase reliability at the time of mounting.

In order to achieve the above possible benefit, an electronic component package according to the present disclosure includes: a resin portion having a first surface; one or more electronic components each having a plurality of external electrodes; and a plurality of extraction electrodes electrically connected to the plurality of external electrodes, wherein only each of the plurality of extraction electrodes is exposed from the resin portion on the first surface, and the plurality of external electrodes are covered with the resin portion.

According to the present disclosure, with the configuration in which only each of the extraction electrodes is exposed with the external electrodes of the electronic component being covered with the resin portion, reliability can be increased at the time of mounting the electronic component package.

### BRIEF DESCRIPTION OF THE SEVERAL VIEWS OF THE DRAWINGS

FIG. 1 is a perspective view of an electronic component package according to a first embodiment of the present disclosure.

FIG. 2 is a cross sectional view of the electronic component package according to the first embodiment of the present disclosure.

FIG. 3 is a bottom view of the electronic component package according to the first embodiment of the present disclosure.

FIG. 4 is a cross sectional view of an electronic component package according to a second embodiment of the present disclosure.

FIG. 5 is a bottom view of the electronic component package according to the second embodiment of the present disclosure.

FIG. 6 is a cross sectional view showing a state in which the electronic component package according to the first embodiment of the present disclosure is mounted.

FIG. 7 is an explanatory diagram of a first step of a method of manufacturing the electronic component package according to the first embodiment of the present disclosure.

FIG. 8 is an explanatory diagram of a second step of the method of manufacturing the electronic component package according to the first embodiment of the present disclosure.

FIG. 9 is an explanatory diagram of a third step of the method of manufacturing the electronic component package according to the first embodiment of the present disclosure.

FIG. 10 is a cross sectional view of an electronic component package according to a third embodiment of the present disclosure.

FIG. 11 is a bottom view of the electronic component package according to the third embodiment of the present disclosure.

FIG. 12 is a cross sectional view of an electronic component package according to a fourth embodiment of the present disclosure.

FIG. 13 is a bottom view of the electronic component package according to the fourth embodiment of the present disclosure.

FIG. 14 is a cross sectional view of an electronic component package according to a fifth embodiment of the present disclosure.

FIG. 15 is a bottom view of the electronic component package according to the fifth embodiment of the present disclosure.

FIG. 16 is a cross sectional view of an electronic component package according to a sixth embodiment of the present disclosure.

FIG. 17 is a bottom view of the electronic component package according to the sixth embodiment of the present disclosure.

FIG. 18 is a plan view of a heat radiation member provided in the electronic component package according to the sixth embodiment of the present disclosure.

FIG. 19 is a side view of the heat radiation member provided in the electronic component package according to the sixth embodiment of the present disclosure.

FIG. 20 is a cross sectional view of a first example in which an extraction electrode is formed on a surface of a substrate in a step of the method of manufacturing the electronic component package according to the present disclosure.

FIG. 21 is a cross sectional view of a second example in which an extraction electrode is formed on a surface of a substrate in a step of the method of manufacturing the electronic component package according to the present disclosure.

FIG. 22 is a cross sectional view of a third example in which an extraction electrode is formed on a surface of a substrate in a step of the method of manufacturing the electronic component package according to the present disclosure.

FIG. 23 is a cross sectional view of a first example in which a resist film is patterned around the extraction electrode in a step of the method of manufacturing the electronic component package according to the present disclosure.

FIG. 24 is a cross sectional view of a second example in which a resist film is patterned around the extraction electrode in a step of the method of manufacturing the electronic component package according to the present disclosure.

### DETAILED DESCRIPTION OF THE DISCLOSURE

A dimensional ratio shown in figures does not necessarily represent an actual dimensional ratio exactly, and may be shown in an exaggerated manner for convenience of explanation. In the description below, when reference is made to a concept regarding the upward direction or downward direction, the upward direction or downward direction is not necessarily meant in an absolute sense, but may be meant in a relative sense in an illustrated posture.

### First Embodiment

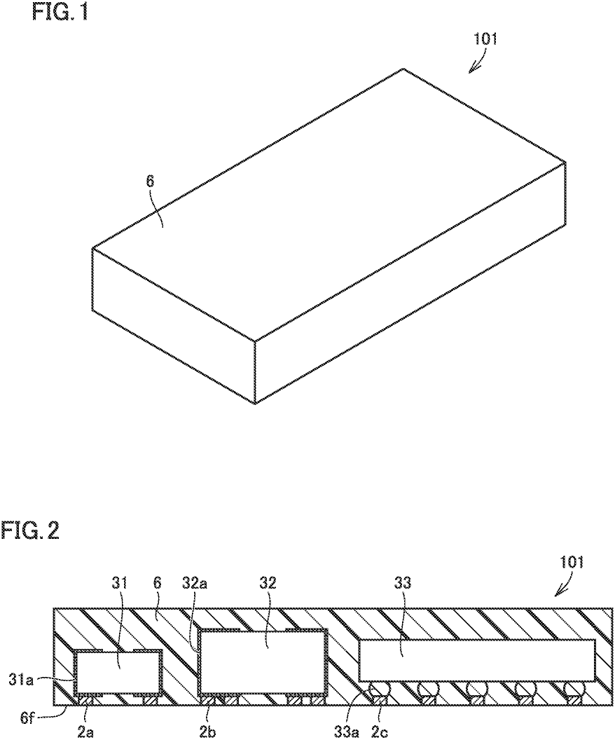

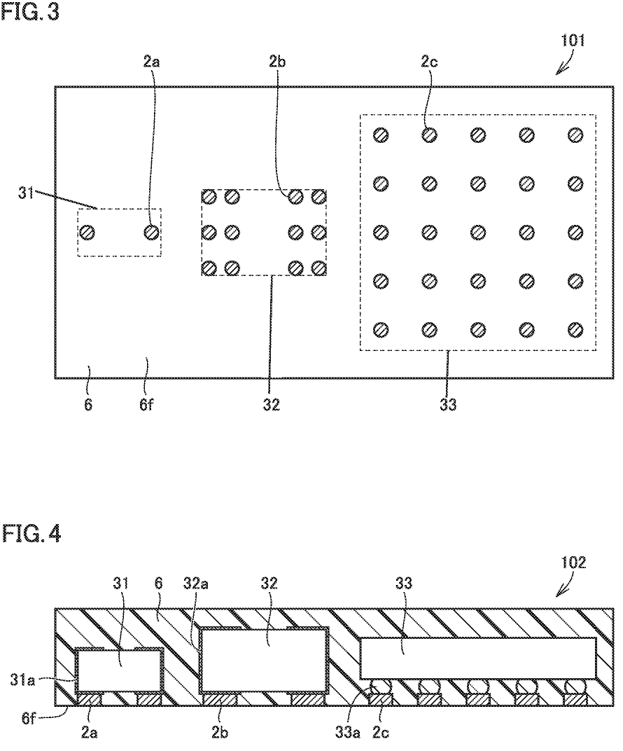

An electronic component package according to a first embodiment of the present disclosure will be described with reference to FIGS. 1 to 3. FIG. 1 is a perspective view of an electronic component package 101 according to the present embodiment. FIG. 2 is a cross sectional view of electronic component package 101. FIG. 3 is a bottom view of electronic component package 101.

Electronic component package 101 according to the present embodiment includes: a resin portion 6 having a first surface 6f; one or more electronic components 31, 32, 33 each having a plurality of external electrodes 31a, 32a, 33a; and a plurality of extraction electrodes 2a, 2b, 2c electrically connected to the plurality of external electrodes 31a, 32a, 33a. Only each of the plurality of extraction electrodes 2a, 2b, 2c is exposed from resin portion 6 on first surface 6f. The plurality of external electrodes 31a, 32a, 33a are covered with resin portion 6.

In the present embodiment, as shown in FIG. 2, external electrode 31a is formed on the top surface, side surface, and bottom surface of electronic component 31. External electrode 32a is formed on the top surface, side surface, and bottom surface of electronic component 32. External electrode 33a is a solder bump. External electrode 33a is connected to the lower surface of electronic component 33.

In the example shown here, the plurality of external electrodes 31a, 32a, 33a include electrodes having different sizes, whereas the plurality of extraction electrodes 2a, 2b, 2c have the same sizes. In this case, the plurality of extraction electrodes 2a, 2b, 2c have the same areas when viewed from below. When the lower surface of electronic component package 101 is viewed, it is viewable that the electrodes having the same areas are arranged. When the lower surface of electronic component package 101 is viewed, electronic components 31, 32, 33 may not be viewable.

In the present embodiment, since external electrodes 31a, 32a, 33a of electronic components 31, 32, 33 are not directly exposed to outside of resin portion 6 and only each of extraction electrodes 2a, 2b, 2c are exposed with external electrodes 31a, 32a, 33a being covered by resin portion 6, no constricted shape is formed in each of the external electrodes at the time of mounting the electronic component package, thereby increasing reliability at the time of mounting.

It is preferable that the portions of the plurality of extraction electrodes exposed from first surface 6f have the same areas. By employing this configuration, connection conditions for mounting on a mother substrate can be advantageously the same. The shape of each extraction electrode exposed from first surface 6f is not limited to a circular shape and may be another shape. Here, attention is paid as to whether or not the areas of the portions of the entire extraction electrodes exposed from first surface 6f are the same, rather than the areas of the members of the extraction electrodes themselves when viewed from below. Therefore, when the extraction electrodes each have a large area when viewed from below and only portions of the extraction electrodes are exposed from first surface 6f, attention is paid to the areas of the exposed portions. The plurality of extraction electrodes may have different shapes as long as they have the same areas. Two or more extraction electrodes having different shapes may be included in the plurality of extraction electrodes. Even when the extraction electrodes are compared and have different shapes, the extraction electrodes preferably have the same areas.

As described in the present embodiment, it is preferable that the plurality of extraction electrodes include a first extraction electrode and a second extraction electrode, the one or more electronic components are a plurality of electronic components, the plurality of electronic components include a first electronic component having a first external electrode on a side surface and a bottom surface, and a second electronic component having a second external electrode that is a solder bump, and the first extraction electrode is connected to the first external electrode and the second extraction electrode is connected to the second external electrode. In the present embodiment, each of extraction electrodes 2a, 2b corresponds to the first extraction electrode, and extraction electrode 2c corresponds to the second extraction electrode. Each of electronic components 31, 32 corresponds to the first electronic component, and electronic component 33 corresponds to the second electronic component. Each of external electrodes 31a, 32a corresponds to the first external electrode, and external electrode 33a corresponds to the second external electrode.

By employing this configuration, even when electronic components 31, 32, 33 are sealed by resin portion 6, the first extraction electrode is connected to the first external electrode in each of electronic components 31, 32 each serving as the first electronic component, thereby drawing out the electrode to the outside of resin portion 6. Also, extraction electrode 2c serving as the second extraction electrode is connected to the second external electrode that is a solder bump in electronic component 33 serving as the second electronic component, thereby drawing out the electrode to the outside of resin portion 6. Therefore, it is possible to avoid the problem of constriction that may occur in the solder bump. That is, although external electrode 33a is a solder bump, it is possible to avoid occurrence of constriction therein. The first electronic component illustrated here has the first external electrode not only on the side surface and the bottom surface but also on the top surface, and such a configuration may be employed.

It should be noted that when it is assumed that external electrode 33a, which is a solder bump, is the second external electrode and electronic component 33 is the second electronic component as illustrated in the present embodiment, it is preferable that a diameter of a portion of the second external electrode at which the second external electrode is bonded to a portion of the second electronic component other than the second external electrode is equal to a diameter of a portion of the second external electrode at which the second external electrode is bonded to the second extraction electrode as shown in FIG. 2.

### Second Embodiment

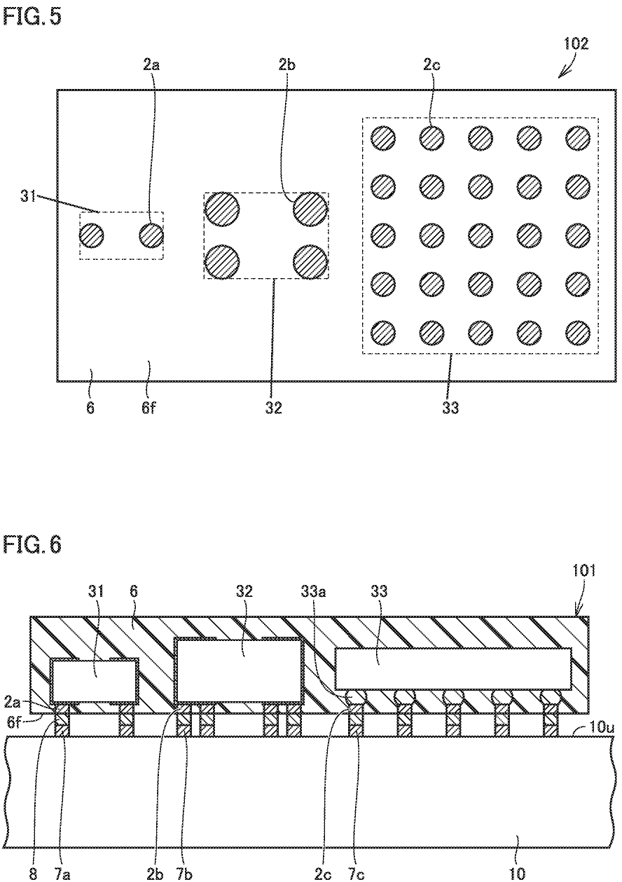

An electronic component package according to a second embodiment of the present disclosure will be described with reference to FIGS. 4 to 5. FIG. 4 is a cross sectional view of an electronic component package 102 according to the present embodiment. FIG. 5 is a bottom view of electronic component package 102. The configuration of electronic component package 102 is basically the same as that of electronic component package 101 described in the first embodiment, but differs in the following points.

In electronic component package 102, the plurality of extraction electrodes 2a, 2b, 2c include an extraction electrode having a first size and an extraction electrode having a second size different from the first size. For example, when it is assumed that each of extraction electrodes 2a, 2c has the first size, extraction electrode 2b has the second size. In other words, the electrodes having different sizes are included in the group of electrodes exposed on the lower surface of electronic component package 102. Here, the group of electrodes exposed on the lower surface includes the two types of electrodes; however, this is just an example and three or more types of sizes of electrodes may be included. Further, not only the sizes but also the shapes may be different.

As shown in the present embodiment, it is preferable that the plurality of extraction electrodes 2a, 2b, 2c include extraction electrodes in which portions exposed from first surface 6f have two or more different areas.

In the present embodiment, since electronic component package 102 includes, as the plurality of extraction electrodes 2a, 2b, 2c, extraction electrodes in which portions exposed from first surface 6f have two or more different areas, electrodes of appropriate sizes can be combined in one electronic component package 102 in accordance with a purpose of use and can be used for mounting.

FIG. 6 shows a state in which electronic component package 101 shown in the first embodiment is mounted. Here, as an example, electronic component package 101 is mounted on a surface 10u of a mother substrate 10. Pad electrodes 7a, 7b, 7c are provided on surface 10u. Pad electrodes 7a, 7b, 7c are arranged to correspond to extraction electrodes 2a, 2b, 2c respectively. Pad electrodes 7a, 7b, 7c are individually connected to extraction electrodes 2a, 2b, 2c via solders 8.

It should be noted that in the first embodiment, electronic component 32 includes two external electrodes 32a and six extraction electrodes 2b are connected to each of two external electrodes 32a. In the second embodiment, electronic component 32 includes two external electrodes 32a and two extraction electrodes 2b are connected to each of two external electrodes 32a. Thus, it is preferable that two or more of the plurality of extraction electrodes are connected to at least one of the plurality of external electrodes. By employing this configuration, even when the area of each extraction electrode is small, a plurality of extraction electrodes can be connected to an external electrode having a large area, so that connection resistance can be reduced. By applying this concept, a difference in size between the external electrodes of the electronic component can be handled by changing the number of electrodes to be arranged without changing the size of each extraction electrode.

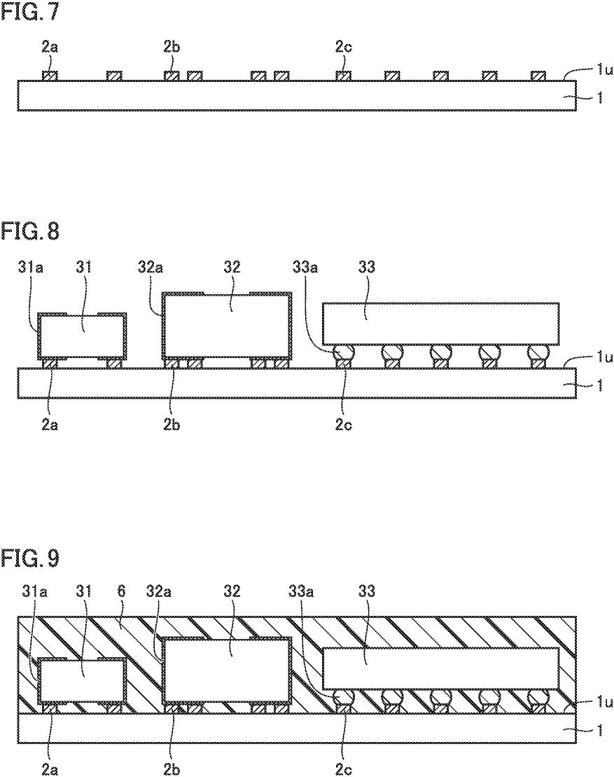

A method of manufacturing the electronic component package will be described with reference to FIGS. 7 to 9. Here, as an example, a manufacturing method for obtaining electronic component package 101 according to the first embodiment will be described.

First, as shown in FIG. 7, a substrate 1 is prepared. Substrate 1 has a surface 1u. On surface 1u, extraction electrodes 2a, 2b, 2c are each formed in advance as a conductor film. Extraction electrodes 2a, 2b, 2c can be formed, for example, by forming a conductive film so as to cover the whole of surface 1u and then patterning the conductive film.

Next, as shown in FIG. 8, electronic components 31, 32, 33 are mounted on surface 1u. External electrode 31a of electronic component 31 is connected to extraction electrode 2a. External electrode 32a of electronic component 32 is connected to extraction electrode 2b. External electrode 33a of electronic component 33 is connected to extraction electrode 2c.

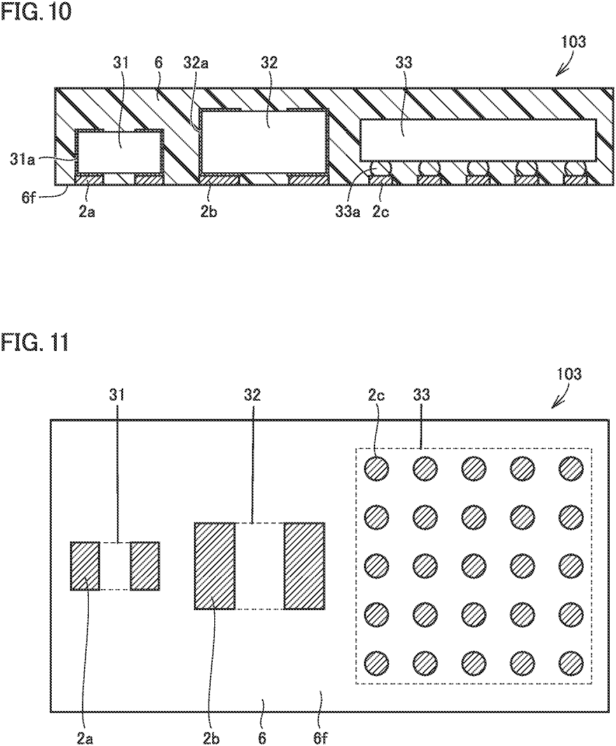

Further, as shown in FIG. 9, resin portion 6 is formed to cover surface 1u and electronic components 31, 32, 33. Resin portion 6 may be formed by molding.

Then, substrate 1 is removed. Substrate 1 can be removed by a known technique. By removing substrate 1, extraction electrodes 2a, 2b, 2c are exposed on the lower surface of resin portion 6. That is, electronic component package 101 shown in FIG. 2 is obtained.

Here, the manufacturing method for obtaining electronic component package 101 in the first embodiment has been described; however, the electronic component package in each of the other embodiments can also be obtained in the same manner by appropriately changing the sizes and arrangement of extraction electrodes 2a, 2b, 2c in FIG. 7.

### Third Embodiment

An electronic component package according to a third embodiment of the present disclosure will be described with reference to FIGS. 10 to 11. FIG. 10 is a cross sectional view of an electronic component package 103 according to the present embodiment. FIG. 11 is a bottom view of electronic component package 103. The configuration of electronic component package 103 is basically the same as that of electronic component package 102 described in the second embodiment, but differs in the following points.

In electronic component package 103, a region in which a third extraction electrode included in the plurality of extraction electrodes 2a, 2b, 2c is exposed on first surface 6f is equal to a region obtained by projecting any one of the plurality of external electrodes onto first surface 6f. For example, extraction electrode 2a may be regarded as the third extraction electrode. In this case, a region in which extraction electrode 2a serving as the third extraction electrode is exposed on first surface 6f is equal to a region obtained by projecting external electrode 31a onto first surface 6f. This condition is established also when extraction electrode 2b is regarded as the third extraction electrode.

In the present embodiment, since the extraction electrode is provided to have the same size as that of the region obtained by projecting the external electrode onto first surface 6f, connection resistance at the time of mounting electronic component package 103 can be reduced.

It has been described that in the above embodiments, resin portion 6 is exposed on the outer surface of the electronic component package; however, this is just an example. The surface of resin portion 6 may be covered with a certain film on any surface of the electronic component package. For example, the upper surface and side surface of resin portion 6 may be covered with a conductive film serving as a shield film. For example, the lower surface of resin portion 6 other than its portions at which the electrodes are exposed may be covered with an insulating film.

### Fourth Embodiment

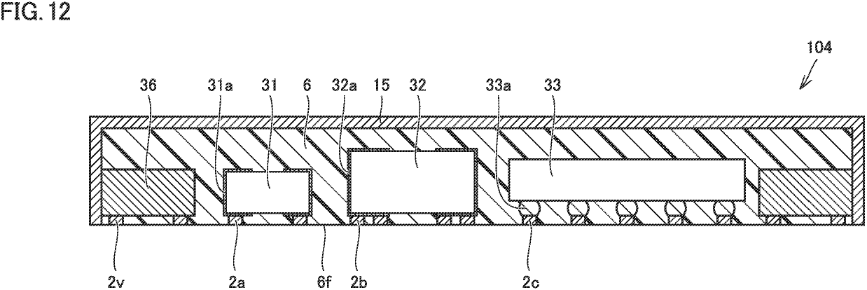

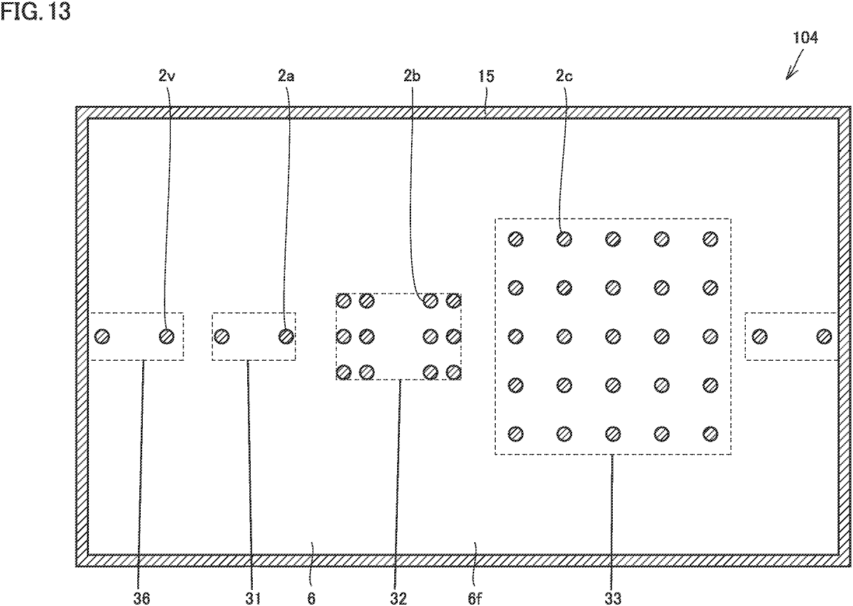

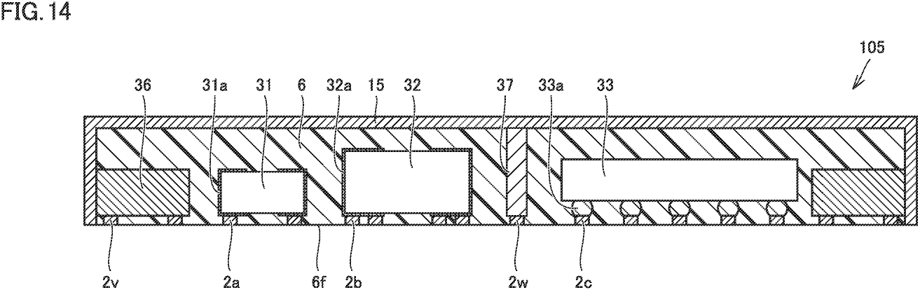

An electronic component package according to a fourth embodiment of the present disclosure will be described with reference to FIGS. 12 to 13. FIG. 12 is a cross sectional view of an electronic component package 104 according to the present embodiment. FIG. 13 is a bottom view of electronic component package 104. The configuration of electronic component package 104 is basically the same as that of electronic component package 101 described in the first embodiment. In electronic component package 104, the upper surface and side surface of resin portion 6 are covered with a shield film 15. Shield film 15 is composed of a conductive film. Shield film 15 is composed of a metal.

In electronic component package 104, a shield connection member 36 is disposed in contact with shield film 15 on each of the side surfaces thereof. Shield connection member 36 is a member mainly composed of a conductor. The main material of shield connection member 36 may be a metal. Shield connection member 36 and shield film 15 on the side surface are electrically connected to each other. That is, a portion of the side surfaces of shield connection member 36 connected to shield film 15 is exposed from resin portion 6.

Shield connection member 36 is not limited to a block composed of one material, and may have a stacked structure. Shield connection member 36 may be formed by combining a conductive material and a non-conductive material. Extraction electrodes 2v are connected to the lower surface of shield connection member 36. The conductor material included in shield connection member 36 is electrically connected to each extraction electrode 2v. Shield connection member 36 is sealed by resin portion 6. The lower surface of extraction electrode 2v is exposed from resin portion 6. That is, extraction electrode 2v is exposed on first surface 6f. Since shield connection member 36 is disposed, extraction electrode 2v and shield film 15 are electrically connected to each other. As with the plurality of extraction electrodes 2a, 2b, 2c, extraction electrodes 2v have the same sizes. That is, the plurality of extraction electrodes 2a, 2b, 2c, 2v have the same areas when viewed from below. When the lower surface of electronic component package 104 is viewed, it is viewable that the electrodes including extraction electrodes 2v and having the same areas are arranged.

As shown here, the plurality of shield connection members 36 may be disposed in one resin portion 6. The plurality of shield connection members 36 are not limited to being disposed along one side surface, and may be disposed in a distributed manner on a plurality of different side surfaces.

In the present embodiment, since shield connection member 36 is present and shield film 15 is therefore electrically connected to extraction electrode 2v exposed on first surface 6f, shield film 15 can be readily set to a ground potential by connecting extraction electrode 2v to the ground electrode, with the result that the components included in electronic component package 104 can be shielded excellently.

### Fifth Embodiment

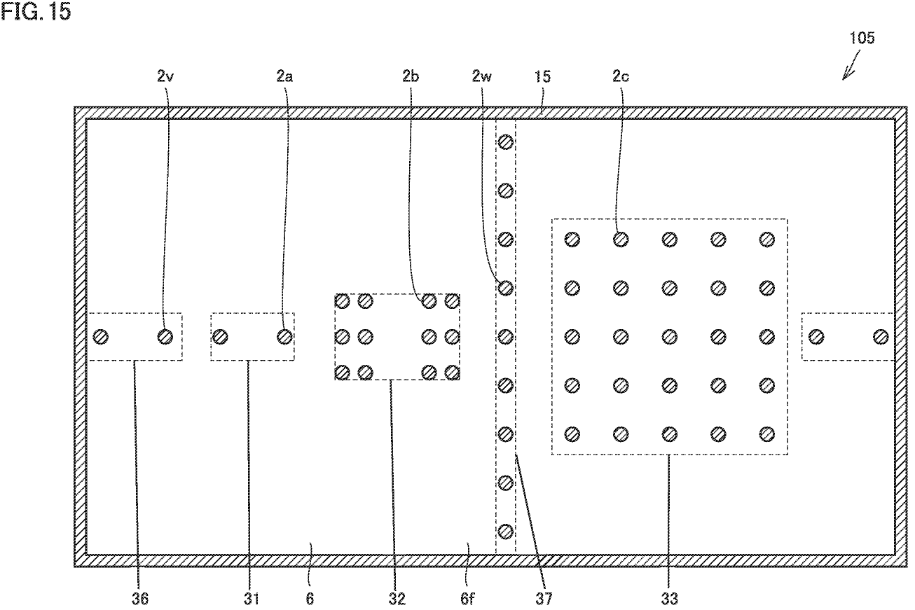

An electronic component package according to a fifth embodiment of the present disclosure will be described with reference to FIGS. 14 to 15. FIG. 14 is a cross sectional view of an electronic component package 105 according to the present embodiment. FIG. 15 is a bottom view of electronic component package 105. The configuration of electronic component package 105 is basically the same as that of electronic component package 104 described in the fourth embodiment. Electronic component package 105 includes a shield wall member 37 disposed to separate electronic component 32 from electronic component 33. Shield wall member 37 is composed of a conductor. Shield wall member 37 is not limited to being composed of one material, and may be composed of a combination of a plurality of types of materials. Shield wall member 37 may have a structure including an insulating coating film.

As shown in FIG. 15, when viewed in a plan view, shield wall member 37 extends from one side surface to reach the other side surface. One end of shield wall member 37 is electrically connected to shield film 15 covering the one side surface, and the other end thereof is electrically connected to shield film 15 covering the other side surface. Resin portion 6 may be substantially completely separated by shield wall member 37. Each of extraction electrodes 2w is connected to the lower end of shield wall member 37. The conductor material included in shield wall member 37 is electrically connected to extraction electrode 2w. Resin portion 6 on the one surface side of shield wall member 37 and resin portion 6 on the other surface side of shield wall member 37 may be connected to each other on the lower end of shield wall member 37 at the portion to which extraction electrode 2w is not connected.

The upper end of shield wall member 37 reaches shield film 15. The upper end of shield wall member 37 reaches the upper end of resin portion 6 and is electrically connected to shield film 15. In order to install shield wall member 37, for example, a plate-shaped member composed of a metal may be fixed to be connected to extraction electrode 2w provided in advance on surface 1u of substrate 1 in the manufacturing method described with reference to FIGS. 7 to 9.

The lower surface of extraction electrode 2w is exposed from resin portion 6. That is, extraction electrode 2w is exposed on first surface 6f. Since shield wall member 37 is disposed, extraction electrode 2w and shield film 15 are electrically connected to each other. As with the plurality of extraction electrodes 2a, 2b, 2c, extraction electrodes 2w have the same sizes. That is, the plurality of extraction electrodes 2a, 2b, 2c, 2v, 2w have the same areas when viewed from below. When the lower surface of electronic component package 105 is viewed, it viewable that electrodes including extraction electrodes 2w and having the same areas are arranged.

In the present embodiment, since shield wall member 37 is disposed to separate electronic component 32 from electronic component 33, shielding between the electronic components can be improved.

In the present embodiment, it has been illustratively described that shield wall member 37 is disposed to extend from the one side surface to reach the other side surface; however, this is just an example. When viewed in a plan view, the one end of shield wall member 37 may be electrically connected to shield film 15 on the one side surface, and the other end of shield wall member 37 may not reach the other side surface and may be terminated before the other side surface. Further, when viewed in a plan view, both the ends of shield wall member 37 may not be connected to shield film 15 on the side surfaces, and may be terminated before shield film 15. Even when shield wall member 37 is not necessarily electrically connected to shield film 15 on the side surfaces, shielding between the electronic components can be improved because shield wall member 37 is disposed to separate the electronic components from each other.

In the present embodiment, it has been illustratively described that shield wall member 37 has a shape of straight line when viewed in a plan view; however, this is just an example. When viewed in a plan view, shield wall member 37 may be a shape of polygonal line or a shape of curve. Shield wall member 37 may be disposed, for example, in the form of an L shape.

### Sixth Embodiment

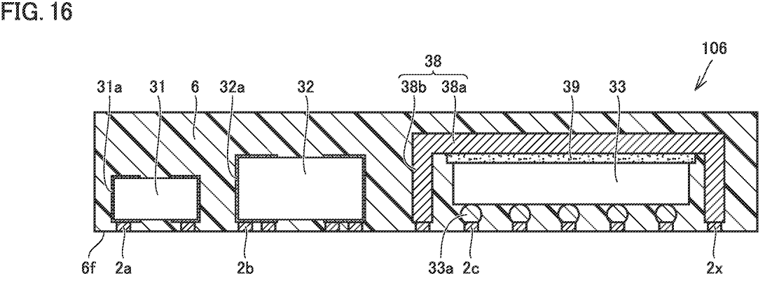

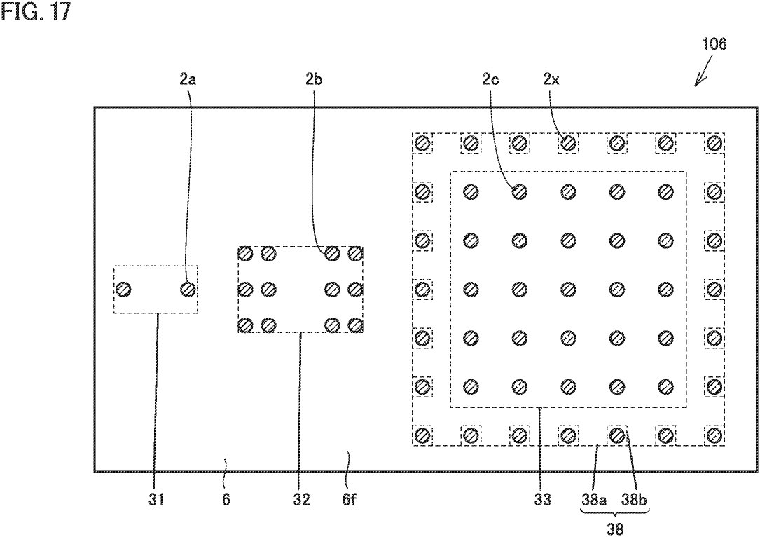

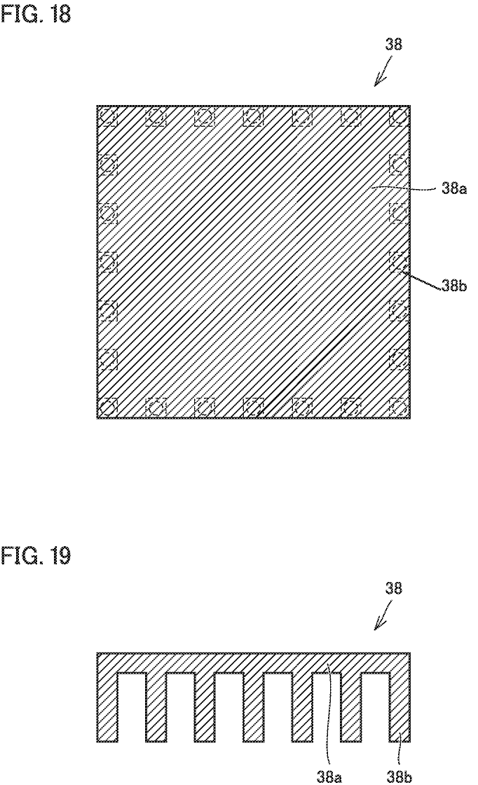

An electronic component package according to a sixth embodiment of the present disclosure will be described with reference to FIGS. 16 to 19. FIG. 16 is a cross sectional view of an electronic component package 106 according to the present embodiment. FIG. 17 is a bottom view of electronic component package 106. The configuration of electronic component package 106 is basically the same as that of electronic component package 101 described in the first embodiment. Electronic component package 106 includes a heat radiation member 38. Heat radiation member 38 includes a flat plate portion 38a and a columnar portion 38b. FIG. 18 is a plan view showing heat radiation member 38 solely and FIG. 19 is a side view showing heat radiation member 38 solely.

Heat radiation member 38 may be composed of a metal. Heat radiation member 38 may be formed in one piece. Flat plate portion 38a of heat radiation member 38 is disposed above electronic component 33. Flat plate portion 38a is connected to electronic component 33 through a certain thermally conductive material. As shown in FIG. 16, flat plate portion 38a may be adhered to the upper surface of electronic component 33 via an adhesive layer 39. When viewed in a plan view, flat plate portion 38a has a size larger than that of electronic component 33, and electronic component 33 is completely hidden under flat plate portion 38a. Columnar portion 38b is a portion protruding downward from the outer edge portion of flat plate portion 38a. Columnar portion 38b is arranged in the form of a loop along the outer edge portion of flat plate portion 38a. Each extraction conductor 2x is connected to the lower end of columnar portion 38b.

The lower surface of extraction electrode 2x is exposed from resin portion 6. That is, extraction conductor 2x is exposed on first surface 6f. Thus, extraction conductor 2x and flat plate portion 38a are electrically connected to each other. As with the plurality of extraction electrodes 2a, 2b, 2c, extraction conductors 2x have the same sizes. That is, the plurality of extraction electrodes 2a, 2b, 2c and the plurality of extraction conductors 2x have the same areas when viewed from below. When the lower surface of electronic component package 106 is viewed, it is viewable that the electrodes or conductors including extraction conductors 2x and having the same areas are arranged.

In the present embodiment, heat generated from electronic component 33 is transmitted to each extraction conductor 2x through flat plate portion 38a and columnar portion 38b of heat radiation member 38. By connecting extraction conductor 2x to a certain conductor, heat radiation from heat radiation member 38 can be promoted. Therefore, heat radiation from electronic component 33 can be promoted. Shielding around electronic component 33 can also be achieved by connecting extraction conductor 2x to an electrode having a ground potential or the like. The upper surface of flat plate portion 38a of heat radiation member 38 may be exposed from resin portion 6.

Although it has been described that electronic component package 106 does not include shield film 15 in the present embodiment, electronic component package 106 may include shield film 15 as described in the fourth embodiment. Both heat radiation member 38 and shield film 15 may be included. In the present embodiment, heat radiation member 38 is shown as having a substantially square shape when viewed in a plan view; however, this is just an example, and heat radiation member 38 may have another shape. Heat radiation member 38 may be provided for the purpose of promoting the heat radiation and improving the shielding performance.

In the above-described embodiments, the description has been made based on such an assumption that a plurality of extraction electrodes are included in one electronic component package; however, it is also conceivable that only one extraction electrode is included in one electronic component. The number of electronic components included in one electronic component package may be one. That is, the electronic component package may include: a resin portion 6 having a first surface 6f; an electronic component having an external electrode; and an extraction electrode electrically connected to the external electrode, wherein only the extraction electrode is exposed from resin portion 6 on first surface 6f, and the external electrode is covered with resin portion 6.

In each of the embodiments described above, it has been described that the cross sectional shape of each of extraction electrodes 2a, 2b, 2c is a quadrangular shape as shown in FIG. 2, for example. However, the cross sectional shape of the extraction electrode is not limited to the quadrangular shape. For example, the extraction electrode may have a tapered shape. In this case, the tapered shape may be such that it becomes thinner in a direction away from the electronic component, or conversely, may be such that it becomes thicker in the direction away from the electronic component. Further, for example, the extraction electrode may have a stepped shape. When the extraction electrode has the tapered shape or the stepped shape, an area of contact with resin portion 6 is increased, thereby improving adhesion between resin portion 6 and the extraction electrode.

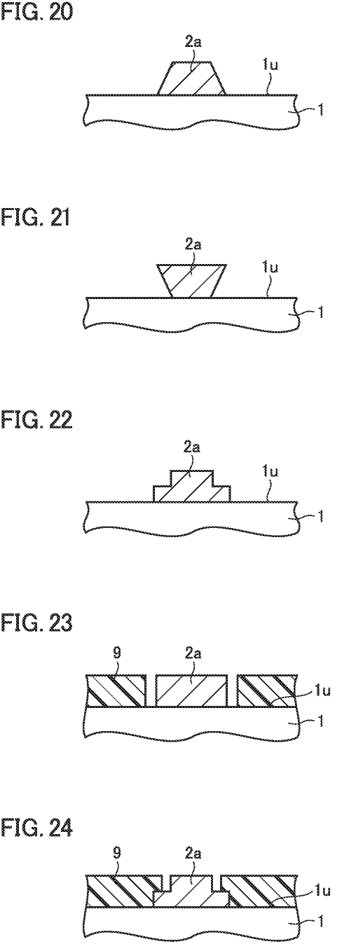

In view of the method of manufacturing the electronic component package, when forming each of extraction electrodes 2a, 2b, 2c as a conductor film on surface 1u of substrate 1 as shown in FIG. 7, the shape of the conductor film may be changed. For example, it is conceivable to form the conductor film to have a shape as shown in each of FIGS. 20, 21, and 22. In each of FIGS. 20 to 22, extraction electrode 2a and the vicinity thereof are shown as an example in an enlarged manner. Since the state in which the extraction electrode is located on surface 1u of substrate 1 is shown here, a relation in increase/decrease of the thickness is opposite to that when actually installing it in the electronic component. In other words, from the conductor film shown in FIG. 20, an extraction electrode can be formed to have such a tapered shape that it becomes thicker in the direction away from the electronic component. From the conductor film shown in FIG. 21, an extraction electrode can be formed to have such a tapered shape that it becomes thinner in the direction away from the electronic component. From the conductor film shown in FIG. 22, an extraction electrode can be formed to have such a stepped shape that its side close to the electronic component is thin and its side away from the electronic component is thick. Here, extraction electrode 2a and the vicinity thereof have been illustrated and described, but the same applies to the other extraction electrodes.

At the stage shown in FIG. 7 in the method of manufacturing the electronic component package, a resist film 9 may be similarly patterned around the extraction electrode as shown in FIG. 23 in an enlarged manner. In this case, after substrate 1 is removed, resist film 9 becomes a part of resin portion 6. With the presence of resist film 9, a solder bridge can be suppressed from being formed between adjacent extraction electrodes when bonding the extraction electrodes using a solder. Such a resist film 9 may be partially disposed only at portions at which the formation of the solder bridge between the extraction electrodes should be suppressed.

Instead of the configuration shown in FIG. 23, for example, the following configuration may be employed: the extraction electrode has a stepped shape and the stepped shape is partially covered with resist film 9 as shown in FIG. 24. In the example shown in FIG. 24, the lower step portion of extraction electrode 2a having a larger area due to the stepped shape is covered with resist film 9, and the upper step portion thereof having a smaller area is not covered with resist film 9 and is exposed. Here, extraction electrode 2a and the vicinity thereof have been illustrated and described, but the same applies to the other extraction electrodes.

It should be noted that a plurality of embodiments of the above embodiments may be appropriately combined and employed.

It should be noted that the embodiments disclosed herein are by way of illustration and example only and are not to be taken by way of limitation. The scope of the present disclosure is defined by the terms of the claims, and is intended to include any modifications within the scope and meaning equivalent to the terms of the claims.

1: substrate; 1u: surface; 2a, 2b, 2c, 2v, 2w: extraction electrode; 2x: extraction conductor; 6: resin portion; 6f: first surface; 7a, 7b, 7c: pad electrode; 8: solder; 9: resist film; 10: mother substrate; 10u: surface; 15: shield film; 31, 32, 33: electronic component; 31a, 32a, 33a: external electrode; 36: shield connection member; 37: shield wall member; 38: heat radiation member; 38a: flat plate portion; 38b: columnar portion; 101, 102, 103, 104, 105, 106: electronic component package.

1. An electronic component package comprising:
a resin portion having a first surface;
one or more electronic components each having a plurality of external electrodes; and
a plurality of extraction electrodes electrically connected to the plurality of external electrodes, wherein
only each of the plurality of extraction electrodes is exposed from the resin portion on the first surface, and
the plurality of external electrodes are covered with the resin portion.

2. The electronic component package according to claim 1, wherein portions of the plurality of extraction electrodes exposed from the first surface have same areas.

3. The electronic component package according to claim 1, wherein portions of some of the plurality of extraction electrodes exposed from the first surface have two or more different areas.

4. The electronic component package according to claim 1, wherein two or more of the plurality of extraction electrodes are connected to at least one of the plurality of external electrodes.

5. The electronic component package according to claim 1, wherein
the plurality of extraction electrodes include a first extraction electrode and a second extraction electrode,
the one or more electronic components are a plurality of electronic components,
the plurality of electronic components include a first electronic component having a first external electrode on at least a bottom surface of the first electronic component, and a second electronic component having a second external electrode being a solder bump, and
the first extraction electrode is connected to the first external electrode, and the second extraction electrode is connected to the second external electrode.

6. The electronic component package according to claim 5, wherein a diameter of a portion of the second external electrode bonded to a portion of the second electronic component other than the second external electrode is equal to a diameter of a portion of the second external electrode bonded to the second extraction electrode.

7. The electronic component package according to claim 1, wherein the plurality of extraction electrodes include a third extraction electrode, and a region of the third extraction electrode exposed on the first surface is equal to a region drawn by projecting any one of the plurality of external electrodes onto the first surface.

8. An electronic component package comprising:
a resin portion having a first surface;
an electronic component having an external electrode; and
an extraction electrode electrically connected to the external electrode, wherein
only the extraction electrode is exposed from the resin portion on the first surface, and
the external electrode is covered with the resin portion.

9. The electronic component package according to claim 2, wherein two or more of the plurality of extraction electrodes are connected to at least one of the plurality of external electrodes.

10. The electronic component package according to claim 3, wherein two or more of the plurality of extraction electrodes are connected to at least one of the plurality of external electrodes.

11. The electronic component package according to claim 2, wherein
the plurality of extraction electrodes include a first extraction electrode and a second extraction electrode,
the one or more electronic components are a plurality of electronic components,
the plurality of electronic components include a first electronic component having a first external electrode on at least a bottom surface of the first electronic component, and a second electronic component having a second external electrode being a solder bump, and
the first extraction electrode is connected to the first external electrode, and the second extraction electrode is connected to the second external electrode.

12. The electronic component package according to claim 3, wherein
the plurality of extraction electrodes include a first extraction electrode and a second extraction electrode,
the one or more electronic components are a plurality of electronic components,
the plurality of electronic components include a first electronic component having a first external electrode on at least a bottom surface of the first electronic component, and a second electronic component having a second external electrode being a solder bump, and
the first extraction electrode is connected to the first external electrode, and the second extraction electrode is connected to the second external electrode.

13. The electronic component package according to claim 4, wherein
the plurality of extraction electrodes include a first extraction electrode and a second extraction electrode,
the one or more electronic components are a plurality of electronic components,
the plurality of electronic components include a first electronic component having a first external electrode on at least a bottom surface of the first electronic component, and a second electronic component having a second external electrode being a solder bump, and
the first extraction electrode is connected to the first external electrode, and the second extraction electrode is connected to the second external electrode.
